(19) United States
(12) Patent Application Publication
(10) Pub. No.: US 2025/0125281 A1
(43) Pub. Date: Apr. 17, 2025

(54) SEMICONDUCTOR PACKAGE ASSEMBLY AND METHODS FOR FORMING THE SAME

(71) Applicant: JCET STATS ChipPAC Korea Limited, Incheon (KR)

(72) Inventors: SeongHwan PARK, Incheon (KR); TaeWan HA, Incheon (KR); YunJeong CHO, Incheon (KR)

(21) Appl. No.: 18/912,636

(22) Filed: Oct. 11, 2024

(30) Foreign Application Priority Data
Oct. 12, 2023 (CN) 202311321647X

(51) Int. Cl. H01L 23/552; H01L 21/56; H01L 21/683; H01L 23/00; H01L 23/29; H01L 25/065

(52) U.S. Cl. CPC H01L 23/552; H01L 21/561; H01L 21/565; H01L 21/6836; H01L 23/295; H01L 24/16; H01L 24/96; H01L 24/97; H01L 25/0655; H01L 2224/16225; H01L 2224/96; H01L 2224/97; H01L 2924/1815

(57) ABSTRACT

A semiconductor package assembly and methods for forming the same is provided. The method comprises: providing a base package substrate comprising a first region and a second region, wherein at least one first-type electronic component is mounted on the first region; attaching a protective layer onto the second region; forming a base mold cap on the first region and the second region to encapsulate the at least one first-type electronic components and the protective layer; removing a portion of the base mold cap that is formed on the second region to form a cavity within the base mold cap and expose the protective layer; detaching the protective layer from the base package substrate; mounting a second-type electronic component onto the second region; and filling a filler material within the cavity.

### TECHNICAL FIELD

The present application generally relates to semiconductor packaging technology, and more particularly, to a semiconductor package assembly and methods for forming the same.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) process is applied, which combines two or more integrated circuit (IC) packages together. The PiP devices can more efficiently use space, and reduce lengths of signal paths between the packages. In a typical PiP device, one or more pre-molded electronic packages are mounted onto a package substrate with other electronic components. Afterwards, an additional mold cap is formed on the package substrate using a molding process, which encapsulates the pre-molded electronic packages and the electronic components to form an entire electronic package. However, the relatively huge thickness of the entire electronic package may result in the potential warpage of the mold cap during a subsequent heating process, i.e., reflowing of solder bumps, which may adversely affect device performance and following fabrication processes.

Therefore, a need exists for a method for forming a semiconductor package assembly with a reduced mold cap thickness.

### SUMMARY OF THE INVENTION

An objective of the present application is to provide a semiconductor package assembly with a reduced mold cap thickness.

According to an aspect of the present application, a method for making a semiconductor package assembly is provided. The method comprises: providing a base package substrate comprising a first region and a second region, wherein at least one first-type electronic component is mounted on the first region; attaching a protective layer onto the second region; forming a base mold cap on the first region and the second region to encapsulate the at least one first-type electronic components and the protective layer; removing a portion of the base mold cap that is formed on the second region to form a cavity within the base mold cap and expose the protective layer; detaching the protective layer from the base package substrate; mounting a second-type electronic component onto the second region; and filling a filler material within the cavity.

According to another aspect of the present application, a semiconductor package assembly is provided. The semiconductor package assembly comprises: a base package substrate comprising a first region and a second region; at least one first-type electronic component mounted on the first region; a base mold cap formed on the base package substrate to encapsulate the at least one first-type electronic components, wherein the base mold cap comprises a cavity that exposes the second region of the base package substrate; a second-type electronic component mounted on the second region; and a filler material filled within the cavity.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1I illustrate various steps of a method for forming a semiconductor package assembly according to a first embodiment of the present application.

FIGS. 2A to 2E illustrate a portion of various steps of a method for forming a semiconductor package assembly according to a second embodiment of the present application.

FIGS. 3A to 3F illustrate a portion of various steps of a method for forming a semiconductor package assembly according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in a typical PiP device, one or more pre-molded electronic packages are mounted onto a package substrate with other electronic components. An additional mold cap may be formed on the package substrate using a molding process, which encapsulates the pre-molded electronic packages and the electronic components to form an entire electronic package. During this process, the pre-molded electronic packages are covered by a redundant mold cap, which is desired to have a uniform thickness, and thus a total thickness of the entire electronic package may be increased. Additionally, due to the possible height differences between the pre-molded electronic packages and the electronic components, the thickness of the mold materials over the pre-molded electronic packages and the electronic components may be different. Such difference in thickness of the mold materials may result in warpage of the mold cap during a subsequent heating process, i.e., reflowing of solder bumps, as thermal stress may vary in different locations of the entire package. The warpage of the mold cap may adversely affect device performance and following fabrication processes.

To address this issue, a new method for forming a semiconductor assembly is provided, in which the pre-molded electronic packages, especially those with significantly greater heights, are mounted after other electronic components are encapsulated by a mold cap. In order for the later mounting of the pre-molded electronic packages, one or more cavities may be formed in the mold cap using a releasable protective layer. The method can be used in forming a semiconductor package assembly which desires smaller package thickness, thus resulting in less warpage when exposed to heating processes such as reflowing.

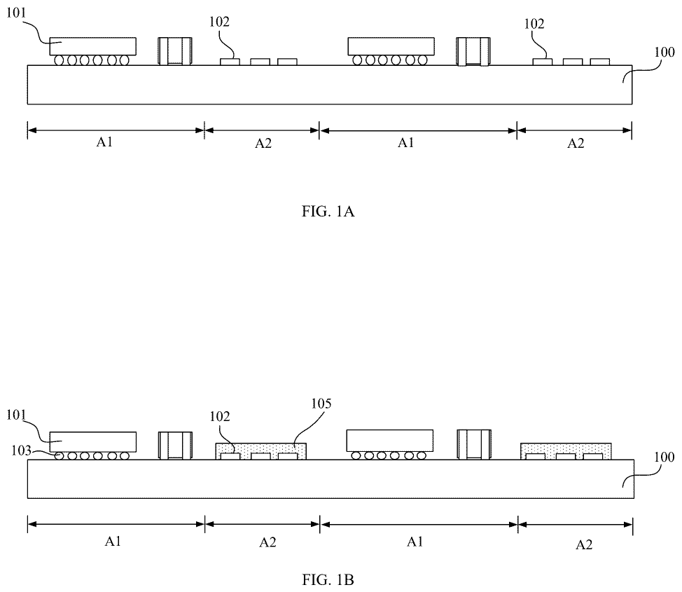

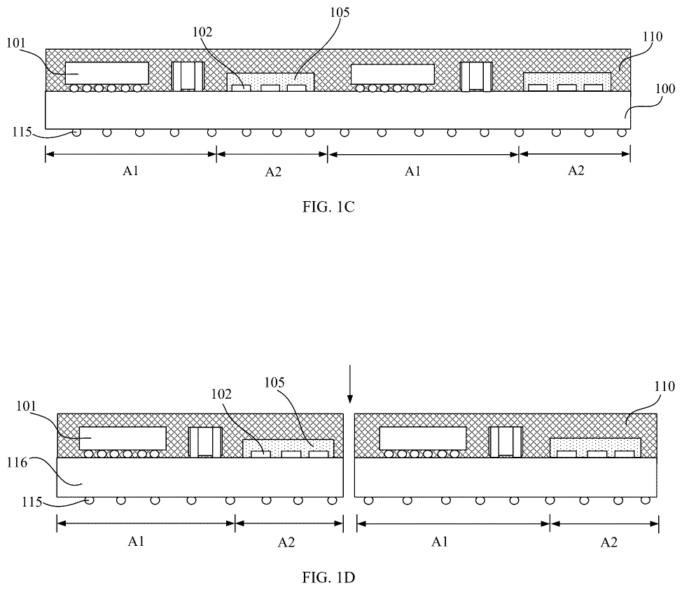

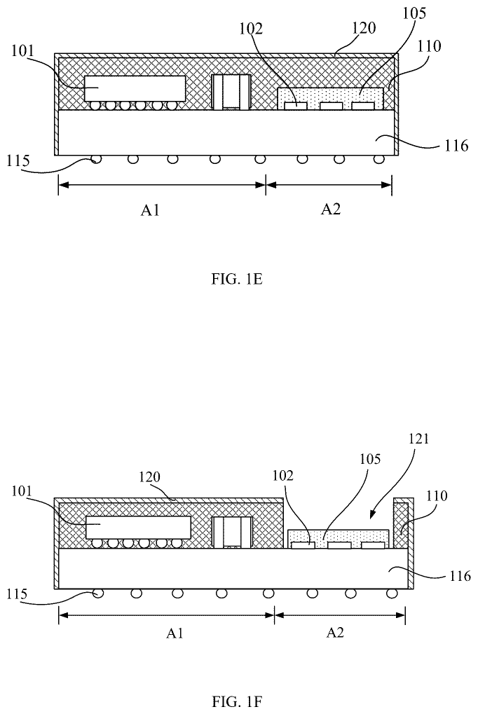

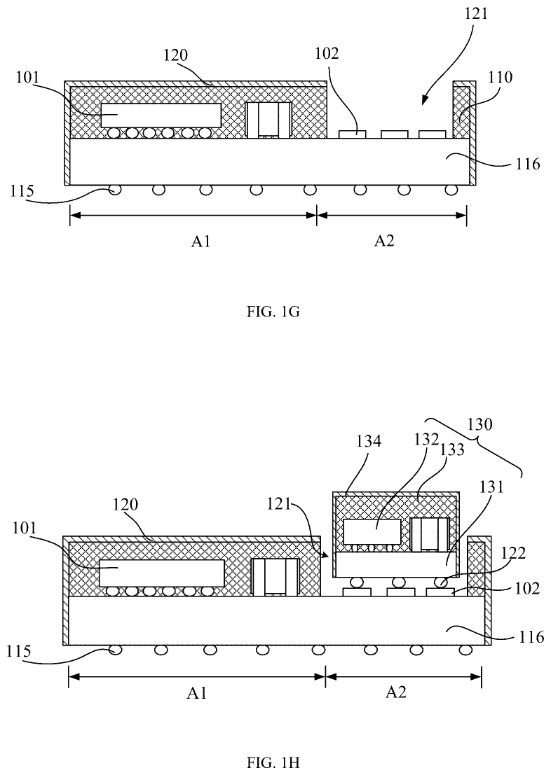

FIGS. 1A to 1I illustrate various steps of a method for forming a semiconductor package assembly according to a first embodiment of the present application. In the following, the method will be described with reference to FIGS. 1A to 1I in more details.

As shown in FIG. 1A, a package substrate strip 100 is provided with embedded interconnect wires. The package substrate strip 100 includes a front surface which may serve as a platform where electronic component(s) and additional electronic packages can be mounted. The package substrate strip 100 may have a plurality of units, and at least one of the units may include a first region A1 and a second region A2. In some embodiments, electronic modules mounted onto the first region A1 and second region A2 may be different. It can be appreciated that the number of the first region(s) A1 and the number of the second region(s) A2 included in the package substrate strip 100 may vary. In the embodiment shown in FIG. 1A, each first region A1 may be adjacent to and between two second regions A2. In other embodiments, it can be appreciated that the first region(s) A1 and the second region(s) A2 may have various arrangements according to various layouts of the semiconductor package assembly.

Furthermore, at least one first-type electronic component 101 is mounted onto the front surface of the first region A1. The first-type electronic components 101 may include various types of electronic devices, such as semiconductor chips, resistors, capacitors or the like. In some embodiments, the first-type electronic components 101 may be electrically connected with interconnect wires embedded in the package substrate strip 100 via a plurality of solder bumps.

Still referring to FIG. 1A, other than the first-type electronic components 101 on the first region A1, the package substrate strip 100 may further include a set of conductive patterns 102 on the second region A2. The conductive patterns 102 may be used for attaching additional electronic modules. In some embodiments, the conductive patterns 102 may be exposed portions of interconnect wires formed within the package substrate strip 100, i.e., contact pads.

As shown in FIG. 1B, a protective layer 105 is attached onto the second region A2 to cover the set of conductive patterns 102. In this way, the conductive patterns 102 can be isolated from potential contamination during subsequent fabrication processes, thus ensuring better reliability of the electrical connection to the conductive patterns 102. In some embodiments, the protective layer 105 may extend significant lengths from respective outermost patterns of the conductive patterns 102 to form sufficient margins, which can guarantee the protection by the protective layer 105. Also, sufficient gaps may be also form between the respective first-type electronic components 101 and the protective layer 105 to avoid potential damage to the first-type electronic components 101 when the protective layer 105 is detached in subsequent processes, as will be elaborated below.

In some preferred embodiments, the protective layer 105 should provide sufficient protection for conductive patterns 102 and in the same time, be easy to get removed with undesired residuals. In the embodiment shown in FIG. 1B, the protective layer 105 is an ultraviolet (UV) sensitive tape, which may be hardened after irradiation by UV light with a certain wavelength range. The hardened ultraviolet sensitive tap may provide effective protection for underlaying conductive patterns 102. In some embodiments, the protective layer 105 may include multiple layers of various UV sensitive tapes or other similar tapes. Furthermore, a UV sensitive tape layer that is in direct contact with the underlying conductive patterns 102 may have high-sticky characteristics to better fit on the surfaces of the conductive patterns 102, avoiding vesicles or gaps between the protective layer 105 and the conductive patterns 102. An upper UV sensitive tape layer may have greater hardness after irradiation by UV light, and therefore can be easily detached. In some other embodiments, the protective layer 105 may include materials such as polymer, plastic, ceramics or the like. Moreover, in some embodiments, height of the conductive patterns 102 is much smaller than that of the first-type electronic components 101. Thus, after attaching the protective layer 105 onto the conductive patterns 102, height of the protective layer 105 relative to the package substrate strip 100 may still be smaller or equal to heights of the first-type electronic components 101.

Next, a base mold cap 110 is formed on the first region A1 and the second region A2 to encapsulate the at least one first-type electronic components 101 and the protective layer 105. As shown in FIG. 1C, the base mold cap 110 covers respective front surfaces of the first-type electronic components 101 and protective layer 105, and a front surface of the package substrate strip 100 not mounted with the electronic components and the protective layer 105 for encapsulation. The base mold cap 110 may be formed using a molding process such as an injection molding process. As mentioned before, since the height of the protective layer 105 may still be smaller or equal to heights of the first-type electronic components 101, the height of the mold cap may be determined according to the heights of the first-type electronic components 101. In other embodiments, it can be appreciated that the relative height of the first-type electronic components 101 and the conductive patterns 102 may vary according to actual needs of the semiconductor package assembly. Materials of the base mold cap 110 may include epoxy, liquid silicone or the like, for example.

Next, a plurality of solder bumps 115 are formed on a back surface of the package substrate strip 100 which is opposite to the front surface where the electronic components are mounted on. The solder bumps 115 may be used for attaching the package substrate strip 100 onto external devices, and are electrically coupled to the conductive wires in the package substrate 100 and thus to the first-type electronic components 101.

Next, as shown in FIG. 1D, after the first-type electronic components 101 and the protective layer 105 are encapsulated, a base package substrate 116, which is one of the various units of the package substrate strip 100, is singulated from the package substrate strip 100 with structures thereon. The singulation may be conducted along boundaries of the first region A1 or the second region A2. After the singulation, the base package substrate 116 includes at least one first region A1 and one second region A2 with respective structures thereon. It can be appreciated that the number of the first regions A1 and the number of the second regions A2 may vary according to actual package designs. The following processes are exemplarily described with reference to the separated base package substrate 116, however, it can be appreciated that the same or similar processes may be applied to the other units singulated from the package substrate strip 100.

Next, as shown in FIG. 1E, a shielding layer 120 is formed at least on the base mold cap 110 of the base package substrate 116, which may help to protect the semiconductor package assembly from electromagnetic interferences. In some examples, the shielding layer 120 may extend to the structures adjacent to the base mold cap 110, and/or other surfaces (e.g., lateral surfaces) of the base mold cap 110, thus providing more effective protection from electromagnetic interferences. In some embodiments, the shielding layer 120 may be formed using a sputtering process or other applicable metal deposition process.

As shown in FIG. 1F, a portion of the base mold cap 110 that is formed on the second region A2 is removed to form a cavity 121 within the base mold cap 110 to expose the protective layer 105 as well as a part or all of the front surface of the second region A2. The cavity 121 is formed for accommodation of electronic modules to be mounted on the second region A2. In some embodiments, a length of the cavity 121 in a horizontal direction may be sufficiently greater that of the protective layer 105 as long as the cavity 121 do not overstep the boundary with the adjacent first regions A1. This may allow for more thorough detaching process of the protective layer 105 subsequently as well as reduce potential contamination to the first-type electronic components 101 on the adjacent first regions A1. In some embodiments, the cavity 121 within the base mold cap 110 is formed by removing a portion of the base mold cap 110 using laser ablation, which has advantages of high accuracy and high efficiency. It can also be appreciated that in other embodiments, the cavity 121 within the base mold cap 110 may be formed by a technique from at least one of milling, drilling, pinching, etching or their combinations. Furthermore, in the embodiment shown in FIG. 1F, the materials of the protective layer 105 and the base mold cap 110 are quite different, thus resulting in quite different removal rates during the same removing procedure. In view of this, the protective layer 105 may serve as a stop layer when removing the mold materials, thus protecting underlying conductive patterns 102 from being damaged. In other words, when the protective layer 105 is exposed during the ablation process, the ablation may stop.

As shown in FIG. 1G, the protective layer 105 is detached from the base package substrate 116, exposing the respective surfaces of the conductive patterns 102 for attaching additional electronic modules. In this embodiment, the detaching of the protective layer 105 may include irradiating the protective layer 102, which is ultraviolet sensitive tape in this case, with ultraviolet light to harden the protective layer 102 and stripping the ultraviolet sensitive tape from the base package substrate 116. In some other embodiments, organic solvents such as acetone, ethyl alcohol, ethyl acetate or the like may be applied to facilitate a thorough removal of the ultraviolet sensitive tape. In some other embodiments, the detaching of the protective layer 105 may include other removing techniques such as pinching, etching or the like.

Next, a second-type electronic component 130 may be mounted onto the second region A2 within the cavity 121. As shown in FIG. 1H, the second-type electronic component 130 may be a pre-molded electronic package covered with a shielding layer 134. To be more specific, the second-type electronic component 130 may include a second package substrate 131 with interconnect wires embedded, at least one third-type electronic component 132 mounted onto the second package substrate 131 and a second mold cap 133 formed on the second package substrate 131 which covers the respective top surfaces of the third-type electronic components 132 and the front surface of the second package substrate 131. Additionally, the shielding layer 134 formed on the flat top surface and lateral surfaces of the second mold cap 133 may continuously extend to the lateral surfaces of the second package substrate 131, which may help to protect the other underlying parts of the pre-molded package from electromagnetic interferences.

Still referring to FIG. 1H, a set of solder bumps 122 are formed on the set of conductive patterns 102, and then the second-type electronic component 130 can be placed on the base package substrate 116 via the set of solder bumps 122, forming electrical connection between the second-type electronic component 130 and the base package substrate 116. Therefore, the second-type electronic component 130 can be connected with the first-type electronic components 101 via the bumps and interconnect wires in the package substrate, forming an integrated semiconductor package assembly. The set of solder bumps 122 may be reflowed after the second-type electronic component 130 is attached onto the conductive patterns 102. In some embodiments, the length of the cavity 121 in the horizontal direction is greater than that of the second-type electronic component 130, thus providing sufficient room for convenient alignment and mounting of the second-type electronic component 130 onto the second region A2.

Furthermore, the second-type electronic component 130 has a thickness greater than that of the at least one first-type electronic component 101. In this embodiment, since the second-type electronic component 130 already includes the second mold cap 133, no extra molding procedure is needed over the second-type electronic component 130. Therefore, the base mold cap 110 may only encapsulate the first-type electronic components 101, saving redundant mold materials over the second-type electronic component 130. In this way, an overall thickness of the semiconductor package assembly may be greatly reduced, thus resulting in less thermal stress and deformation during subsequent heating processes. Additionally, since the first-type electronic components 101 and the second-type electronic component 130 are encapsulated by the respective mold caps separately, the heights of the respective mold caps may substantially correspond to the respective heights of the first-type electronic component 101 and the second-type electronic component 130. Therefore, differences between the mold materials over the first-type electronic components 101 and the second-type electronic component 130 may be reduced as well, thus reducing non-uninform deformation of the semiconductor package assembly during subsequent heating processes. In this way, the top surfaces of the base mold cap 110 and the second-type electronic component 130 may be parallel to each other, thus further improving uniformity of extra modules added on subsequently. However, it can also be appreciated that the height of second-type electronic component 130 relative to that of the at least one first-type electronic component 101 may vary according to actual needs of the package design.

Next, as shown in FIG. 1I, a filler material 140 is filled within the cavity 121 to cover the surfaces of the solder bumps, the conductive patterns 102, the second-type electronic component 130 as well as the second region A2, thus protecting electrical connection structures from potential contamination and forming the semiconductor package assembly 150. The filler material 140 may fill the gap between the second-type electronic component 130 and the base mold cap 110, which provides mechanical support for the second-type electronic component 130, thereby allowing for better accommodation of the second-type electronic component 130 within the cavity 121 and stronger attachment of the second-type electronic component 130 onto the second region A2.

In some embodiments, the semiconductor package assembly 150 can be applied in any semiconductor devices which desire a smaller package thickness, such as in highly integrated circuit devices or the like.

In the embodiment shown in FIGS. 1A to 1I, the second-type electronic component 130 may have a preformed shielding layer, while in some other embodiments, the shielding layer of the second-type electronic component may be formed along with the shielding layer over the first-type electronic components. For example, a shielding layer may be formed after a filler material is filled within the cavity, such that the shielding layer may cover at least the base mold cap, the second-type electronic component and the filler material.

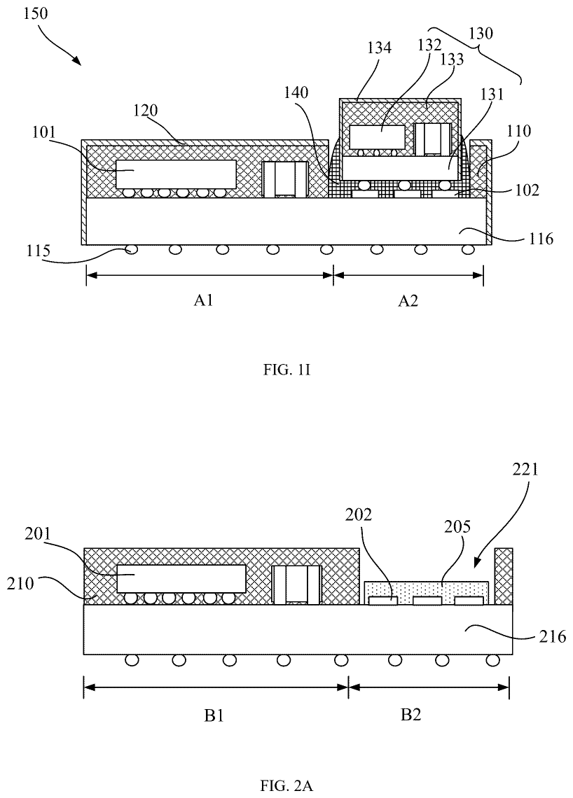

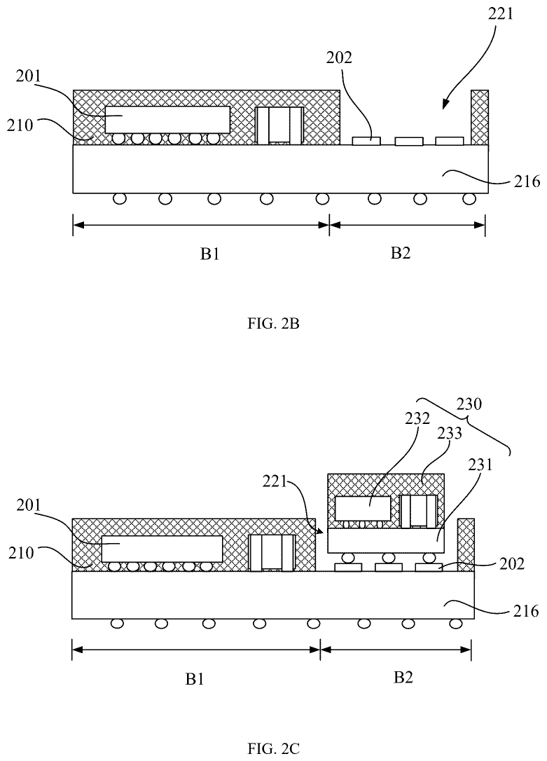

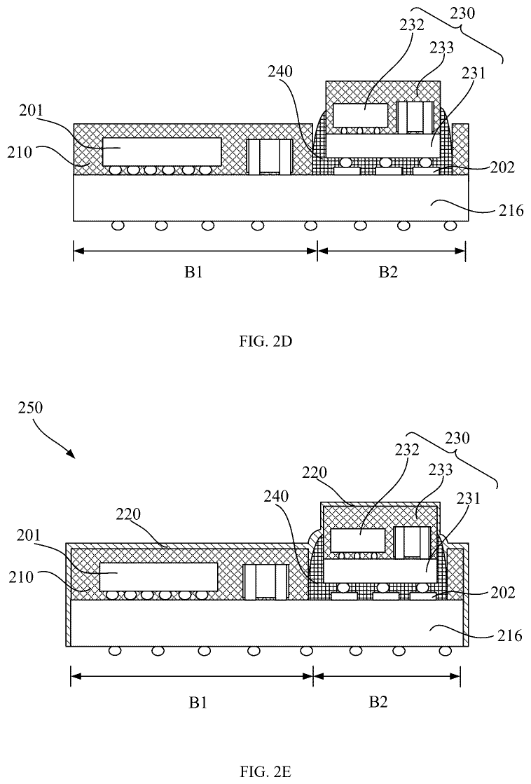

FIGS. 2A to 2E illustrate a portion of various steps of a method for forming a semiconductor package assembly according to a second embodiment of the present application. It should be noted that the method may include the similar steps illustrated in FIGS. 1A to 1D, which will not be elaborated in detail here for simplicity, before taking the steps illustrated in FIGS. 2A to 2E. To be more specific, the method may include steps prior to the step shown in FIG. 2A, including: providing a package substrate strip having a plurality of units, and at least one of the units may include a first region and a second region, where at least one first-type electronic component is mounted on the first region and a set of conductive patterns may be included on the second region; attaching a protective layer onto the second region to cover the set of conductive patterns; forming a base mold cap on the first region and the second region to encapsulate the at least one first-type electronic components and the protective layer; and then a base package substrate, which is one of the various units of the package substrate strip, is singulated from the package substrate strip with structures thereon. Next, the following steps for forming a semiconductor package assembly according to the second embodiment of the present application will be described with reference to FIGS. 2A to 2E in more detail. It should be noted that the following processes are exemplarily described with reference to the separated base package substrate, however, it can be appreciated that the same or similar processes may be applied to the other units singulated from the package substrate strip.

As shown in FIG. 2A, a portion of the base mold cap 210 that is formed on the second region B2 is removed to form a cavity 221 within the base mold cap 210 to expose the protective layer 205 as well as a part or all of the front surface of the second region B2. The details of the formation process of the cavity 221 may be similar to those illustrated in the formation process of the cavity 121 shown in FIG. 1F.

Next, as shown in FIG. 2B, the protective layer 205 is detached from the base package substrate 216, exposing the respective surfaces of the conductive patterns 202 for attaching additional electronic modules. The details of the detaching process of the protective layer 205 may be similar to those illustrated in the detaching process of the protective layer 105 shown in FIG. 1G.

Next, as shown in FIG. 2C, a second-type electronic component 230 may be mounted onto the second region B2 within the cavity 221. In some embodiments, the second-type electronic component 230 may be a pre-molded electronic package. The pre-molded electronic package may include a second package substrate 231 with interconnect wires embedded, at least one third-type electronic component 232 mounted onto the second package substrate 231 and a second mold cap 233 formed on the second package substrate 231. In some embodiments, the thickness of the second-type electronic component 230 may be greater than that of the first-type electronic components 201. The details of the mounting process of the second-type electronic component 230 may be similar to those illustrated in the mounting process of the second-type electronic component 130 shown in FIG. 1H.

Next, as shown in FIG. 2D, a filler material 240 is filled within the cavity 221 to cover the surfaces of solder bumps, the conductive patterns 202, the second-type electronic component 230 as well as the second region B2. Next, as shown in FIG. 2E, a shielding layer 220 is formed on the base package substrate 216 to cover at least the base mold cap 210, the second-type electronic component 230 and the filler material 240, thereby forming the semiconductor package assembly 250. The shielding layer 220 may extend from the base mold cap 210 to the second-type electronic component 230 through the filler material 240. In some examples, the shielding layer 220 may extend to the structures adjacent to the base mold cap 210, and/or other surfaces (e.g., lateral surfaces) of the base mold cap 210. In this way, the shielding layer 220 may be a continuous layer covering front surfaces and lateral surfaces of all structures formed on the base package substrate 216, which may provide more sufficient protection for the semiconductor package assembly 250 from electromagnetic interferences.

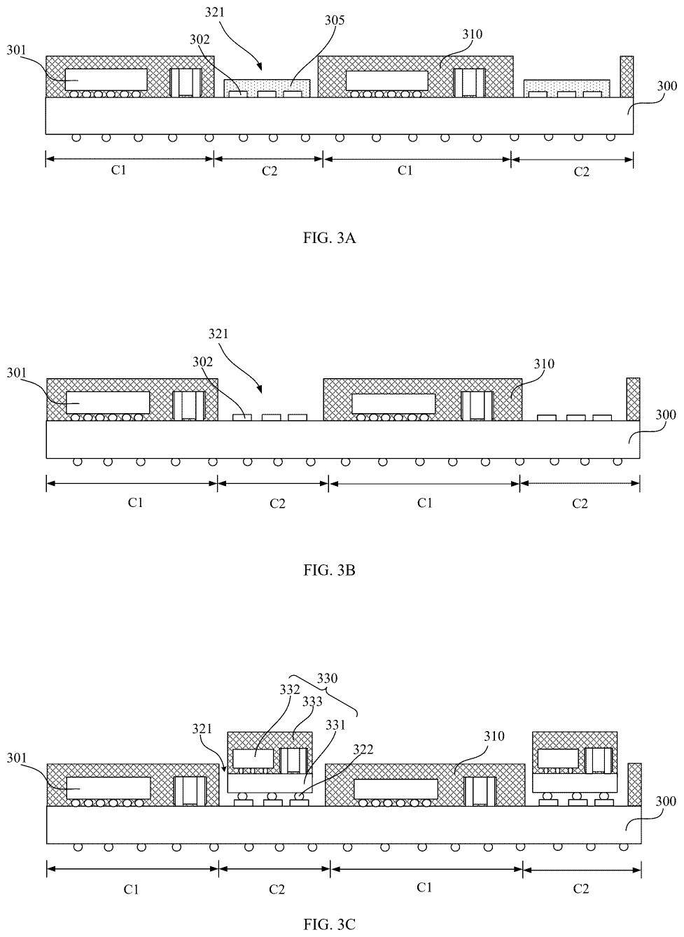

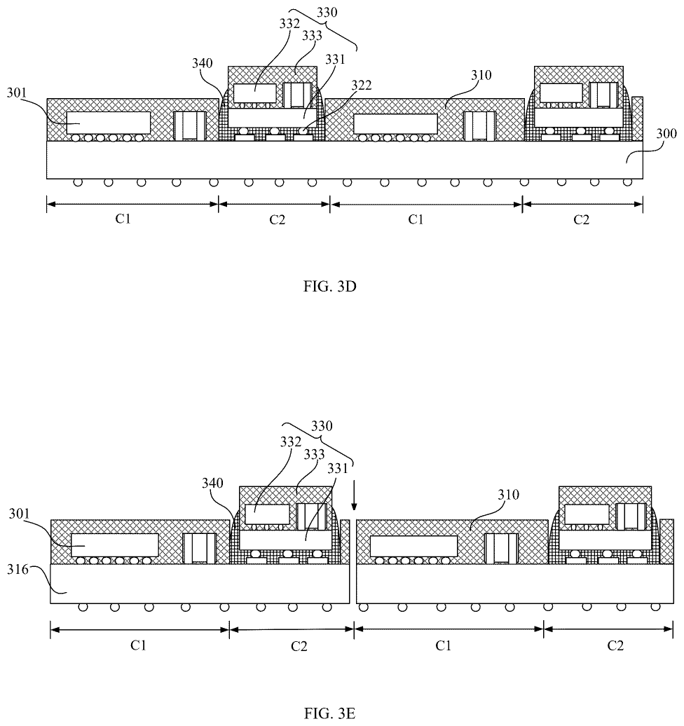

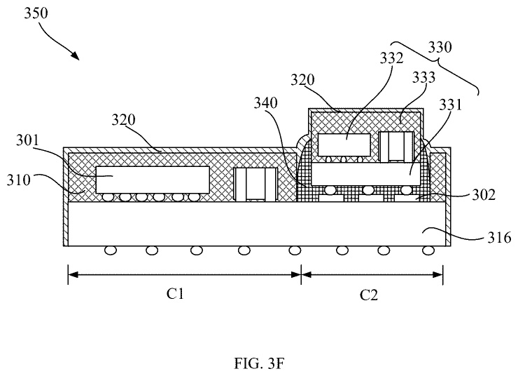

FIGS. 3A to 3F illustrate a portion of various steps of a method for forming a semiconductor package assembly according to a third embodiment of the present application. In the embodiment, a base package substrate is singulated from a package substrate strip after removing a portion of a base mold cap that is formed on a second region of the base package substrate. It should be noted that the method may include the similar steps illustrated in FIGS. 1A to 1C, which will not be elaborated in detail here for simplicity, before taking the steps illustrated in FIGS. 3A to 3F. To be more specific, the method may include steps prior to the step shown in FIG. 3A, including: providing a package substrate strip having a plurality of units, and at least one of the units may include a first region and a second region, where at least one first-type electronic component is mounted on the first region and a set of conductive patterns may be included on the second region; attaching a protective layer onto the second region to cover the set of conductive patterns; and forming a base mold cap on the first region and the second region to encapsulate the at least one first-type electronic components and the protective layer. Next, the following steps for forming a semiconductor package assembly according to the third embodiment of the present application will be described with reference to FIGS. 3A to 3F in more detail.

As shown in FIG. 3A, a portion of the base mold cap 310 that is formed on the second region C2 is removed to form a cavity 321 within the base mold cap 310 to expose the protective layer 305 as well as a part or all of the front surface of the second region C2. The details of the formation process of the cavity 321 may be similar to those illustrated in the formation process of the cavity 121 shown in FIG. 1F.

Next, as shown in FIG. 3B, the protective layer 305 is detached from the base package substrate 316, exposing the respective surfaces of the conductive patterns 302 for attaching additional electronic modules. The details of the detaching process of the protective layer 305 may be similar to those illustrated in the detaching process of the protective layer 105 shown in FIG. 1G.

Next, as shown in FIG. 3C, a second-type electronic component 330 is mounted onto the second region C2 within the cavity 321. In some embodiments, the second-type electronic component 330 may be a pre-molded electronic package. The pre-molded electronic package may include a second package substrate 331 with interconnect wires embedded, at least one third-type electronic component 332 mounted onto the second package substrate 331 and a second mold cap 333 formed on the second package substrate 331. In some embodiments, the thickness of the second-type electronic component 330 may be greater than that of the first-type electronic components 301. The details of the mounting process of the second-type electronic component 330 may be similar to those illustrated in the mounting process of the second-type electronic component 130 shown in FIG. 1H.

Next, as shown in FIG. 3D, a filler material 340 is filled within the cavity 321 to cover the surfaces of the solder bumps, the conductive patterns 302, the second-type electronic component 330 as well as the second region C2. Since the precedent processes including the forming of the cavity 321, the detaching of the protective layer 305, the mounting of the second-type electronic component 330 and the filling of the cavity 321 are conducted on different regions of the same package substrate strip 300, the accuracy and efficiency of the processes may be further improved.

Next, as shown in FIG. 3E, a base package substrate 316, which is one of the various units of the package substrate strip 300, is singulated from the package substrate strip 300 with structures thereon. Next, as shown in FIG. 3F, a shielding layer 320 is formed on the base package substrate 316 to cover at least the base mold cap 310, the second-type electronic component 330 and the filler material 340, thereby forming the semiconductor package assembly 350. The shielding layer 320 may extend from the base mold cap 310 to the second-type electronic component 330 through the filler material 340. In some examples, the shielding layer 320 may further extend to the structures adjacent to the base mold cap 310, and/or other surfaces (e.g., lateral surfaces) of the base mold cap 310. In this way, the shielding layer 320 may provide more sufficient protection for the semiconductor package assembly 350 from electromagnetic interferences.

In some embodiments, the semiconductor package assembly can be applied in any semiconductor devices which desire a smaller package thickness and reduced electromagnetic interferences, such as in highly integrated circuit devices or the like.

While the exemplary method for forming a semiconductor package assembly of the present application is described in conjunction with corresponding figures, it will be understood by those skilled in the art that modifications and adaptations to the method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor package assembly, the method comprising:
providing a base package substrate comprising a first region and a second region, wherein at least one first-type electronic component is mounted on the first region;
attaching a protective layer onto the second region;
forming a base mold cap on the first region and the second region to encapsulate the at least one first-type electronic components and the protective layer;
removing a portion of the base mold cap that is formed on the second region to form a cavity within the base mold cap and expose the protective layer;
detaching the protective layer from the base package substrate;
mounting a second-type electronic component onto the second region; and
filling a filler material within the cavity.

2. The method of claim 1, wherein the second-type electronic component is a pre-molded electronic package.

3. The method of claim 1, wherein the second-type electronic component has a thickness greater than that of the at least one first-type electronic component.

4. The method of claim 1, wherein removing a portion of the base mold cap that is formed on the second region comprises:
removing a portion of the base mold cap using laser ablation.

5. The method of claim 1, wherein the protective layer is an ultraviolet sensitive tape, and detaching the protective layer from the base package substrate comprises:
irradiating the ultraviolet sensitive tape with ultraviolet light; and
stripping the ultraviolet sensitive tape from the base package substrate.

6. The method of claim 1, wherein the base package substrate comprises a set of conductive patterns on the second region, and attaching a protective layer onto the second region comprises:
attaching the protective layer onto the second region to cover the set of conductive patterns.

7. The method of claim 6, wherein mounting a second-type electronic component onto the second region comprises:
forming a set of solder bumps on the set of conductive patterns;
placing the second-type electronic component on the set of solder bumps; and
reflowing the set of solder bumps.

8. The method of claim 1, wherein the base package substrate is a unit of a package substrate strip having a plurality of units, and wherein before removing a portion of the base mold cap that is formed on the second region, the method further comprises:
singulating the base package substrate from the package substrate strip; and
forming a shielding layer at least on the base mold cap of the base package substrate.

9. The method of claim 8, wherein the second-type electronic component is a pre-molded electronic package covered with a shielding layer.

10. The method of claim 1, wherein after filling a filler material within the cavity, the method further comprises:
forming a shielding layer on the base package substrate to cover at least the base mold cap, the second-type electronic component and the filler material.

11. The method of claim 10, wherein the base package substrate is a unit of a package substrate strip having a plurality of units, and wherein after removing a portion of the base mold cap that is formed on the second region, the method further comprises:
singulating the base package substrate from the package substrate strip.

12. The method of claim 10, wherein the base package substrate is a unit of a package substrate strip having a plurality of units, and wherein before removing a portion of the base mold cap that is formed on the second region, the method further comprises:
singulating the base package substrate from the package substrate strip.

13. A semiconductor package assembly, comprising:
a base package substrate comprising a first region and a second region;
at least one first-type electronic component mounted on the first region;
a base mold cap formed on the base package substrate to encapsulate the at least one first-type electronic components, wherein the base mold cap comprises a cavity that exposes the second region of the base package substrate;
a second-type electronic component mounted on the second region; and
a filler material filled within the cavity.

14. The semiconductor package assembly of claim 13, wherein the second-type electronic component is a pre-molded electronic package.

15. The semiconductor package assembly of claim 14, wherein the pre-molded electronic package is covered with a shielding layer.

16. The semiconductor package assembly of claim 13, wherein the second-type electronic component has a thickness greater than that of the at least one first-type electronic component.

17. The semiconductor package assembly of claim 13, further comprising:
a shielding layer formed at least on the base mold cap.

18. The semiconductor package assembly of claim 17, wherein the shielding layer extends from the base mold cap to the second-type electronic component through the filler material.

19. The semiconductor package assembly of claim 13, wherein the cavity is formed by the following process:
attaching a protective layer onto the second region;
forming a portion of the base mold cap on the second region;
removing the portion of the base mold cap that is formed on the second region to expose the protective layer; and
detaching the protective layer from the base package substrate.
